(19) United States
(12) Patent Application Publication
(10) Pub. No.: US 2023/0184860 A1
(43) Pub. Date: Jun. 15, 2023

(54) SYSTEMS AND METHODS FOR GENERATING MULTI-CONTRAST MRI IMAGES

(71) Applicant: Shanghai United Imaging Intelligence Co., Ltd., Shanghai (CN)

(72) Inventors: Xiao Chen, Cambridge, MA (US); Lin Zhao, Athens, GA (US); Zhang Chen, Brookline, MA (US); Yikang Liu, Cambridge, MA (US); Shanhui Sun, Lexington, MA (US); Terrence Chen, Lexington, MA (US)

(73) Assignee: Shanghai United Imaging Intelligence Co., Ltd., Shanghai (CN)

(21) Appl. No.: 17/550,667

(22) Filed: Dec. 14, 2021

(51) Int. Cl. G01R 33/56; G06T 7/00

(52) U.S. Cl. CPC G01R 33/5601; G01R 33/5608; G06T 7/0012; G06T 2207/20081; G06T 2207/20084

(57) ABSTRACT

Described herein are systems, methods, and instrumentalities associated with generating multi-contrast MRI images associated with an MRI study. The systems, methods, and instrumentalities utilize an artificial neural network (ANN) trained to jointly determine MRI data sampling patterns for the multiple contrasts based on predetermined quality criteria associated with the MRI study and reconstruct MRI images with the multiple contrasts based on under-sampled MRI data acquired using the sampling patterns. The training of the ANN may be conducted with an objective to improve the quality of the whole MRI study rather than individual contrasts. As such, the ANN may learn to allocate resources among the multiple contrasts in a manner that optimizes the performance of the whole MRI study.

### BACKGROUND

Magnetic resonance imaging (MRI) has become a very important tool for disease detection, diagnosis, and treatment monitoring. An MRI study of an anatomical structure such as the brain may involve multiple images, each of which may have a unique contrast (e.g., Tl-weighted, T2-weighted, fluid attenuated inversion recovery (FLAIR), etc.) and may provide respective underlying physiologic information. Since MRI is an intrinsically slow imaging technique, such a multi-cast MRI study may need to be accelerated. Conventional acceleration techniques may treat each of the multiple contrasts as an independent case, and under-sample and reconstruct MRI signals (e.g., k-space signals) with a goal to achieve optimal results for each individual contrast. Using these techniques, sampling patterns and reconstruction algorithms may be developed independently and/or solely for each contrast, without leveraging information that may be shared among the multiple contrasts. As a result, while the image obtained for each contrast may be optimized, the output of the whole MRI study may become sub-optimal, for example, with respect to reconstruction quality and/or acquisition time.

Accordingly, systems, methods, instrumentalities are desired for improving the quality of multi-contrast MRI studies by jointly optimizing the sampling and/or reconstruction operations associated with the multiple contrasts.

### SUMMARY

Described herein are systems, methods, and instrumentalities associated with generating MRI images for a multi-contrast MRI study that includes at least a first MRI contrast (e.g., Tl-weighted) and a second MRI contrast (e.g., T2-weighted). An apparatus configured to perform the image generation task may determine one or more quality criteria (e.g., an overall acceleration rate or scan time) associated with generating a first MRI image characterized by the first contrast and a second MRI image characterized by the second contrast. Based on the quality criteria, the apparatus may determine, using an artificial neural network (ANN), a first MRI data sampling pattern for generating the first MRI image and a second MRI data sampling pattern for generating the second MRI image. The first and second MRI data sampling patterns may be used to acquire respective first and second sets of under-sampled MRI data, which may then be used by the ANN to reconstruct the first and second MRI images. The ANN may be trained to determine the first MRI sampling pattern in connection (e.g., jointly) with the second MRI data sampling patterns in order to meet the quality criteria. The ANN may also be trained to generate the first MRI image in connection (e.g., jointly) with the second MRI images in order to meet the quality criteria.

In examples, the ANN described herein may be trained to generate the first MRI image and the second MRI image in a sequential order (e.g., using a recurrent neural network), where the second MRI image may be generated subsequent to and based on the first MRI image. In examples, the ANN described herein may be trained to generate the first MRI image in parallel with the second MRI image (e.g., using a convolutional neural network). In examples, the quality criteria described herein may be further associated with a third MRI image and the ANN may be trained to determine a third MRI data sampling pattern for generating the third MRI image, wherein the third MRI data sampling pattern may be determined in connection with at least one of the first MRI data sampling pattern or the second MRI data sampling pattern, and the third MRI image may be generated in connection with at least one of the first MRI image or the second MRI image so as to satisfy the quality criteria.

In examples, the training of the ANN described above may include receiving a training dataset that comprises MRI data, determining a first estimated sampling pattern for generating a first MRI contrast image, obtaining first under-sampled MRI data by applying the first estimated sampling pattern to the MRI data comprised in the training dataset, and generating the first MRI contrast image based on the first under-sampled MRI data. The training may further include determining a second estimated sampling pattern for generating a second MRI contrast image, obtaining second under-sampled MRI data by applying the second estimated sampling pattern to the MRI data comprised in the training dataset, and generating the second MRI contrast image based on the second under-sampled MRI data. The first and second MRI contrast images generated during such a training iteration may be compared with respective first and second ground truth MRI images to determine a loss between the MRI images generated by the ANN and the ground truth MRI images. The loss may then be backpropagated through the ANN to update the parameters of the ANN. In examples, the parameters of the ANN may also be adjusted based on one or more other losses including, for example, a loss between a target overall quality metric (e.g., a target overall acceleration rate) and an actual quality metric (e.g., an actual overall acceleration rate) accomplished by the ANN. In examples, the parameters of the ANN may be adjusted based on a combined loss such as an average of the losses associated with the multiple contrasts.

### BRIEF DESCRIPTION OF THE DRAWINGS

A more detailed understanding of the examples disclosed herein may be had from the following description, given by way of example in conjunction with the accompanying drawing.

FIG. 1 is a simplified block diagram illustrating an example neural network for generating multi-contrast MRI images in accordance with one or more embodiments describe herein.

FIG. 2 is a simplified block diagram illustrating an example neural network structure for adaptively generating multi-contrast MRI images in accordance with one or more embodiments describe herein.

FIG. 3 is a simplified block diagram illustrating example operations that may be associated with training an artificial neural network to generate multi-contrast MRI images in accordance with one or more embodiments described herein.

FIG. 4 is a simplified flow diagram illustrating example operations that may be performed for training a neural network in accordance with one or more embodiments described herein.

FIG. 5 is a simplified block diagram illustrating example components of an apparatus that may be configured to perform the tasks described in one or more embodiments provided herein.

### DETAILED DESCRIPTION

The present disclosure is illustrated by way of example, and not by way of limitation, in the figures of the accompanying drawings.

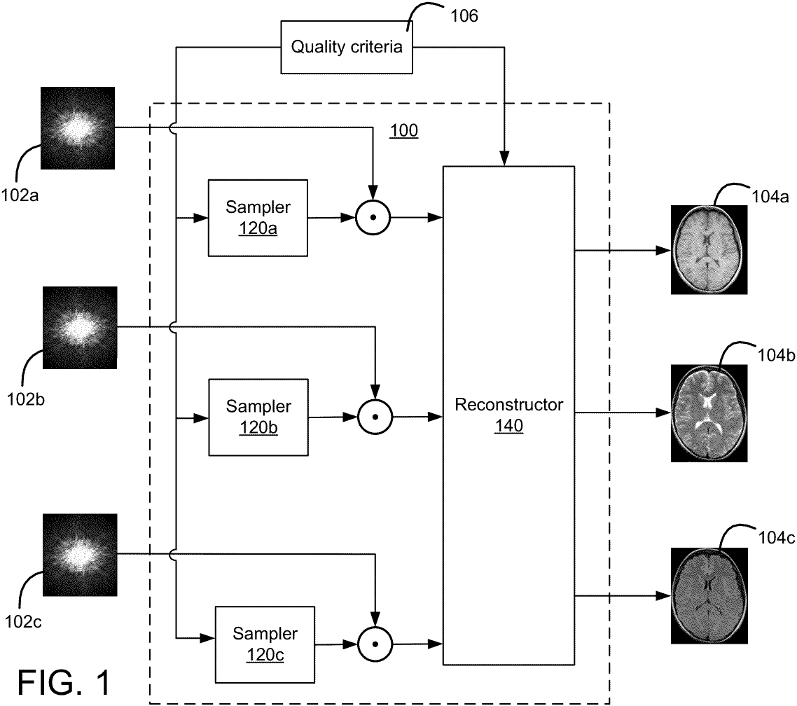

FIG. 1 is a simplified block diagram illustrating an example artificial neural network (ANN) 100 that may be trained to generate (e.g., reconstruct) MRI images characterized by respective contrasts. As shown, the ANN 100 may be configured to generate the MRI images based on spatial frequency and/or phase information (e.g., 102a, 102b, and/or 102c shown in FIG. 1) about an anatomical structure (e.g., the human brain) collected by an MRI scanner. Such spatial frequency and/or phase information may be referred to herein as k-space, k-space data, or k-space information. The information may be collected for purposes of conducting an MRI study (e.g., a brain MRI study) that may involve multiple MRI contrast images such as T1-weighted image 104a, T2-weighted image 104b, and/or fluid attenuated inversion recovery (FLAIR) image 104c. As will be described in greater detail below, the ANN 100 may be trained to determine respective (e.g., first, second, and third) MRI data sampling patterns for acquiring under-sampled MRI data from k-space 102a-102c and the ANN may be further trained to generate (e.g., reconstruct) MRI images 104a-104c based on the under-sampled MRI data.

The ANN may include respective samplers (e.g., 120a, 120b, and 120c shown in FIG. 1) configured to determine the MRI data sampling patterns described above. Each of the MRI data sampling patterns may include a sampling mask or map indicating where data is to be collected in k-space 102a-102c in order to generate a specific MRI contrast image (e.g., T1 image 104a, T2 image 104b, FLAIR image 104c, etc.). The ANN may further include a reconstructor (e.g., 140 shown in FIG. 1) configured to generate MRI images 104a-104c based on the under-sampled data acquired using the MRI data sampling patterns. Reconstructor 140 may be trained to, for example, remove artifacts (e.g., such as aliasing artifacts) caused by the under-sampling such that MRI images 104a-c may have the same (e.g., or substantially similar) quality as if they were generated based on fully sampled k-space data.

ANN 100 may be trained to determine the respective MRI data sampling patterns and/or reconstruction techniques that are applied to MRI images 104a-104c based on quality criteria 106 associated with the MRI images (e.g., associated with an MRI study based on the multi-contrast images). Quality criteria 106 may include, for example, an overall acceleration rate associated with the MRI study (e.g., for generating MRI images 104a-104c), an overall scan time associated with the MRI study, respective image qualities of MRI images 104a-104c, a quality metric associated with a downstream application that utilizes one or more of MRI images 104a-104c, and/or the like. ANN 100 may be configured to obtain (e.g., receive) quality criteria 106 in different manners and/or from difference sources such as, e.g., from preset configuration information, based on information received (e.g., in real time) by ANN 100, from an upstream or downstream device or application, etc. Further, it should be noted that the connections shown in FIG. 1 between quality criteria 106 and sampler 120a-120c and between quality criteria 106 and reconstructor 140 are meant to illustrate that the operations of sampler 120a-120c and/or reconstructor 140 may be governed by quality criteria 106. The connections do not necessarily mean that quality criteria 106 are provided as an input to the samplers and/or reconstructor, even though that may be the case in some examples.

ANN 100 may be trained to determine the sampling patterns and/or reconstruction techniques for the different contrasts in connection with each other (e.g., jointly or in relation to each other) such that an overall quality of the MRI study may be optimized (e.g., by meeting quality criteria 106) even if the quality of an individual MRI image (e.g., 104a, 104b, or 104c) may not be at an optimal level. For example, given an overall acceleration rate a, ANN 100 may jointly determine the sampling patterns and/or reconstruction techniques to be applied to the various contrasts with an objective to satisfy the overall acceleration rate a. In this way, while the respective acceleration rate ai for each contrast i may not be the highest, the overall acceleration rate a of the MRI study may still be accomplished, for example, by increasing acceleration rate aₗ for a first contrast and decreasing acceleration rate a₂ for a second contrast, etc.

Each sampler 120a-120c may include one or more fully connected layers followed by respective sigmoid activation functions that are trained to determine a respective MRI data sampling pattern for the corresponding contrast (e.g., Tl-weighted, T2-weighted, FLAIR, etc.). The MRI data sampling pattern may then be provided to an MRI scanner to acquire under-sampled MRI data for reconstructing the contrast image. Reconstructor 140 may include a convolutional neural network (CNN) such as a fully-connected CNN trained to reconstruct MRI images 104a-104c based on respective under-sampled MRI data obtained by the MRI scanner. In examples, reconstructor 160 may include multiple sub-networks (e.g., multiple CNNs) each designated to reconstruct MRI images with a respective contrast. Based on such a network structure, MRI images 104a-104c may be generated in parallel using the respective sub-networks. In examples, reconstructor 160 may include a recurrent neural network (RNN) configured to generate MRI images 104a-104c in a sequential order. For example, using the RNN, reconstructor 160 may generate MRI image 104b subsequent to and/or based on MRI image 104a, and may generate MRI image 104c subsequent to and/or based on at least one of MRI image 104a or MRI image 104b. In this manner, reconstructor 160 may be able to improve the quality of a present MRI contrast image by utilizing information or knowledge gained from a previously reconstructed MRI contrast image. The RNN structure may also provide flexibility for handling additional contrast(s) without incurring a significant increase in the network size (e.g., a separate network may not be needed for each additional contrast).

In examples, reconstructor 140 may be configured to process the under-sampled MRI data for the various contrasts as images, which may be obtained by applying an inverse Fourier transform such as an inverse Fast Fourier Transform (FFT) to the under-sampled MRI data. In examples, reconstructor 140 may include multiple convolutional layers each of which may include a plurality of convolution kernels or filters with respective weights (e.g., operating parameters of the reconstructor 260) that may be configured to extract features from the input images. The convolutional layers may be zero-padded to have the same output size as the input, and the convolution operations may be followed by batch normalization and/or ReLu activation (e.g., leaky-ReLU activation). The features extracted by the convolutional layers may then be down-sampled through one or more pooling layers and/or one or more fully connected layers to obtain a representation of the features, for example, in the form of one or more feature maps. Reconstructor 140 may further include one or more un-pooling layers and one or more transposed convolutional layers. Through the un-pooling layers, reconstructor 140 may up-sample the extracted features and further process the up-sampled features through the one or more transposed convolutional layers (e.g., via a plurality of deconvolution operations) to derive one or more up-scaled or dense feature maps. The dense feature maps may then be used to predict MRI images 104a-104c, which may be substantially free of artifacts (e.g., aliasing artifacts) that would otherwise be present due to the under-sampling. As will be described in greater detail below, reconstructor 140 may learn, through an end-to-end training process, respective parameters (e.g., weights of the various filters and kernels of reconstructor 260) for reconstructing MRI images 104a-104c in connection with each other so as to meet quality criteria 106.

There may be multiple reasons or motivations for balancing resources (e.g., in terms of scan times or acceleration rates) among different MRI contrasts. For example, certain contrasts may be associated with smooth signals and, as such, may require fewer high frequency signals for reconstruction. Accordingly, resources may be diverted to collecting high frequency signals for other contrasts. As another example, certain k-space information may be shared by multiple contrasts because even though the contrasts may be different, the underlying anatomical structure is still the same. Therefore, the reconstruction of a second contrast image (e.g., T2-weighted image 104b) may re-use at least some information that has already been collected for a first contrast image (e.g., T1-weighted image 104a). As yet another example, multiple contrasts may be analyzed and/or combined in a specific manner to facilitate a down-stream study or application, and that manner may determine how resources and/or priorities should be assigned while reconstructing images for the multiple contrasts. For instance, with T1 mapping, multiple contrast images acquired at different inversion time points may be fitted to an exponential recovery signal model to calculate the T1 value for each pixel. The accuracy of such a value may largely depend on the first few time points where signal intensity may change dramatically. Therefore, more data should be collected (e.g., sampled) for the first few time points so as to reconstruct those time points at a higher quality. As yet another example reason for employing deep-learning methods to balance the reconstruction of MRI images 104a-c, some contrasts may take a longer time to acquire and therefore, given a desired quality level and/or a fixed time budget, it may be difficult to determine an optimal balance among the multiple contrasts manually and/or heuristically.

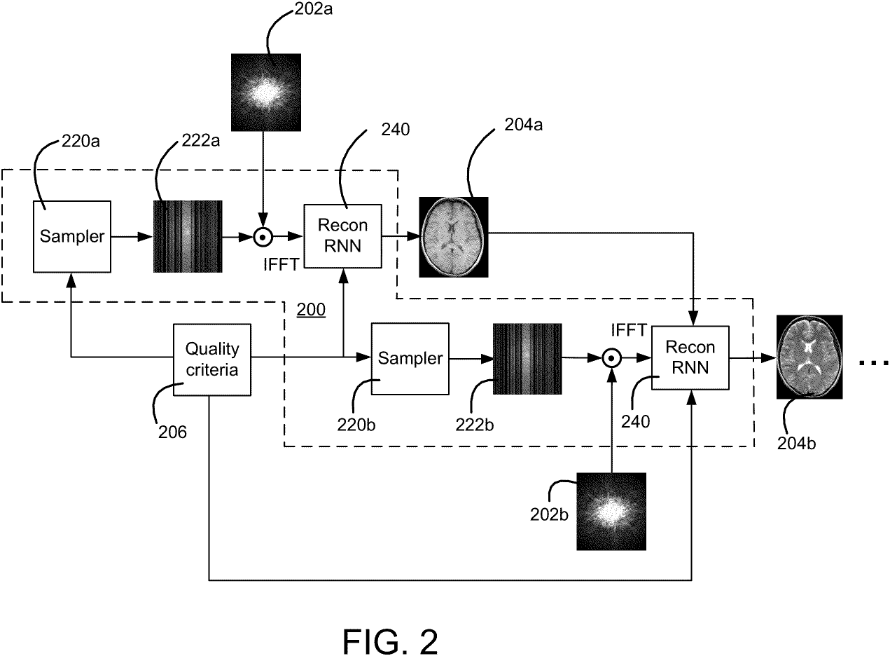

FIG. 2 illustrates an example neural network 200 (e.g., neural network 100 shown in FIG. 1) that may be used to sample a k-space (e.g., 202a, 202b, etc.) and reconstruct multi-contrast MRI images (e.g., 204a, 204b, etc.) based on quality criteria 206 associated with the MRI images. As shown, neural network 200 may include one or more samplers (e.g., sampler 220a, 220b, etc.) and one or more reconstructors (e.g., RNN 240). The samplers may be trained to determine respective sampling patterns (e.g., 222a, 222b, etc.) for the multiple MRI contrasts in a manner that satisfies quality criteria 206. For example, ANN 200 may, through sampler 220a (e.g., sampler 120a of FIG. 1), determine first sampling pattern 222a that may be used (e.g., by an MRI scanner) to acquire first under-sampled MRI data for generating first MRI contrast image 204a (e.g., a T1-weighted image). ANN 200 may, through sampler 220b (e.g., sampler 120b of FIG. 1), determine second sampling pattern 222b that may be used (e.g., by the MRI scanner) to acquire second under-sampled MRI data for generating second MRI contrast image 204b (e.g., a T2-weighted image). And although not shown in FIG. 2, those skilled in the art will understand that ANN 200 may determine additional sampling patterns associated with additional MRI contrast images (e.g., a FLAIR image) using additional samplers. Further, it should be noted here that the connections shown in FIG. 2 between quality criteria 206 and sampler 220a-220b and between quality criteria 206 and reconstructor 240 are meant to illustrate that the operations of the samplers and/or reconstructor may be governed by quality criteria 206. The connections do not necessarily mean that quality criteria 206 are provided as an input to the samplers and/or reconstructor, even though that may be the case in some examples.

ANN 200 may determine the various sampling patterns (e.g., 222a, 222b, etc.) in connection with each other (e.g., as opposed to independently) so that scan resources may be allocated among the multiple contrast images to meet quality criteria 206. As will be described in greater detail below, the samplers of ANN 200 may learn to determine the respective sampling patterns for the multiple contrasts based on vectors and/or matrices (e.g., containing random values) that represent initial sampling locations for the multiple contrasts.

While FIG. 2 may show that reconstructor 240 is implemented as an RNN, those skilled in the art will appreciate that other types of network structures (e.g., a cascading network) may also be used to accomplish the tasks associated with reconstructing MRI images 204a, 204b, etc. Using the RNN structure shown in FIG. 2 as an example, reconstructor 240 may be trained to generate the multi-contrast MRI images jointly (e.g., in connection with each other) so that the parameters and/or operations associated with generating each of the multi-contrast MRI images may be coordinated to satisfy quality criteria 206. For example, reconstructor 240 may generate MRI image 204a based on sampling pattern 222a and subsequently generating MRI image 204b based on sampling pattern 222b and MRI image 204a (e.g., using MRI image 204a as an additional input for generating MRI image 204b). In this manner, reconstructor 240 may generate the multi-contrast images adaptively, for example, utilizing information or knowledge gained from a previously reconstructed MRI contrast image.

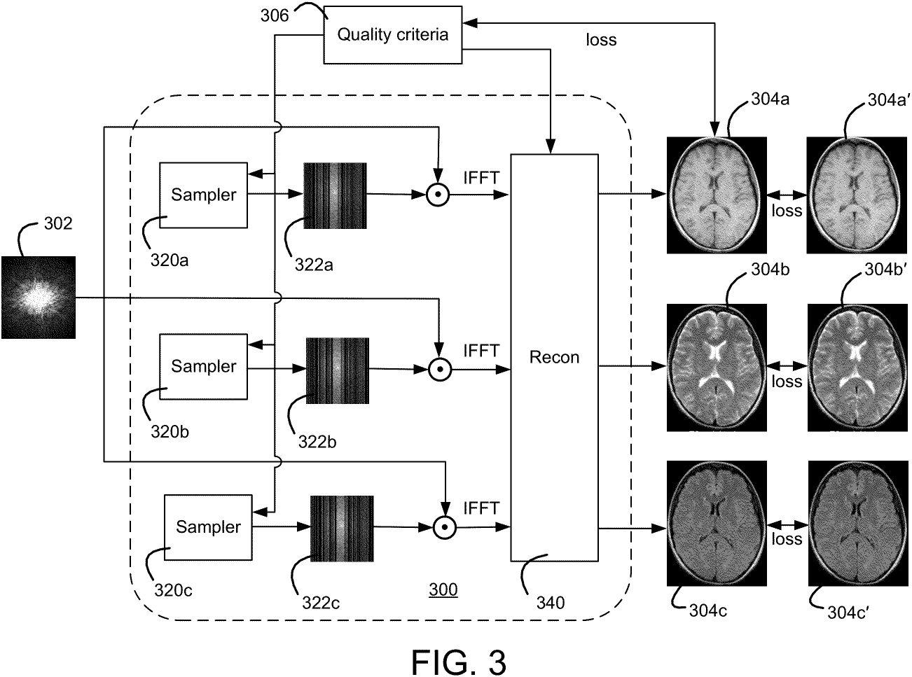

FIG. 3 illustrates example operations that may be associated with training an artificial neural network (ANN) 300 (e.g., ANN 100 of FIG. 1 and/or ANN 200 of FIG. 2) to perform the multi-contrast MRI image reconstruction tasks describe herein. The training may be conducted using a training dataset 302 that may include fully sampled k-space data (e.g., to simulate data acquired by an MRI scanner during a practical MRI procedure). During the training, ANN 300 may, through respective samplers (e.g., 320a, 320b, and 320c) associated with multiple MRI contrasts (e.g., Tl-weighted, T2-weighted, and FLAIR), predict respective sampling patterns (e.g., 322a, 322b, and 322c) that may be used to acquire under-sampled MRI data for the multiple contrasts. In examples, the samplers may predict the sampling patterns for the multiple contrasts based on respective vectors or matrices containing random values (e.g., there may be one random value for each potential sampling location in the k-space). During an initial training iteration, the samplers may, based on the vectors or matrices, make a prediction for the real probability at which data may be collected from each sampling location of the k-space. The samplers may generate respective probability maps for the multiple contrasts to indicate the predicted sampling probabilities. For example, for each potential sampling location of the k-space, the probability map for a contrast may include a corresponding value (e.g., in the range of (0,1)) that indicate the probability at which data may be collected from the sampling location. For instance, a location with a value of 0.8 may indicate that the location has a 80% probability of being sampled while a location with a value of 0.5 may indicate that the location has a 50% probability of being sampled.

Based on the probability maps, the samplers of ANN 300 may further derive corresponding binary masks (with values of zeros and ones) that represent sampling patterns 322a-322c in which an MRI scanner may sample the k-space to acquire data for the multiple contrasts. In examples, the samplers may derive the binary masks or sampling patterns 322a-322c by binarizing the probability maps based on a threshold value. For instance, with a threshold value of 0.5, each location in the probability maps having a value greater than 0.5 may be assigned a value of 1 indicating that data is to be collected from the location, and each location in the probability maps having a value equal to or smaller than 0.5 may be assigned a value of 0 indicating that data is not to be collected from the location.

Upon deriving sampling patterns 322a-322c for the multiple contrasts, ANN 300 may apply the sampling patterns to the fully sampled k-space data of training dataset 302 to obtain under-sampled MRI data for the multiple contrasts (e.g., this operation emulates the operation of an MRI scanner during a practical MRI procedure). Subsequently, ANN 300 may, through reconstructor 340, generate respective MRI images (e.g., 304a, 304b, and 304c) for the multiple contrasts based on the under-sampled MRI data obtained using sampling patterns 322a-322c (e.g., the under-sampled MRI data may be converted to respective images via IFFT before being provided to reconstructor 340). ANN 300 may then compare the MRI images generated by reconstructor 340 with corresponding ground truth images (e.g., 304a′, 304b′, and 304c′) and adjust the parameters of ANN 300 (e.g., weights associated with the various neurons, kernels and/or filters of sampler 320a-320c and reconstructor 340) based on one or more losses determined from the comparison. These losses may include, for example, a respective loss associated with each contrast image generated by reconstructor 340 (e.g., between images 304a and 304a′, between images 304b and 304b′, and/or between images 304c and 304c′) or a combined loss associated with all of the contrast images generated by reconstructor 340 (e.g., as an average of the individual losses described above).

In examples, ANN 300 may also adjust its parameters based on a difference between target quality criteria 306 and the actual quality accomplished by ANN 300 during the training iteration. For instance, quality criteria 306 may include a target overall acceleration rate a associated with generating the multi-contrast MRI images, and ANN 300 may determine a loss based on a difference between the target overall acceleration rate a and the actual overall acceleration rate accomplished by ANN 300. The actual overall acceleration rate accomplished by ANN 300 may be determined, for example, based on individual acceleration rates (e.g., ao, as, and a₂) accomplished for the multiple contrasts (e.g., as a sum of the individual acceleration rates). ANN 300 may then adjust its parameters based on the loss and in this manner ANN 300 may learn an optimal combination of individual acceleration rates ao, as, and a₂ for the multiple contrasts that may satisfy the target acceleration rate a. In examples, ANN 300 may also adjust its parameters based on a loss associated with a down-stream task that utilizes one or more of MRI images 304a-304c. For instance, ANN 300 may calculate a difference between a fitted T1 map generated using MRI image 304a and a ground truth T1 map, and ANN 300 may adjust its parameters based on the calculated difference.

ANN 300 may calculate the losses described herein using various loss functions including, for example, an L1, L2, or structural similarity index (SSIM) based loss function. Once the losses are determined, ANN 300 may backpropagate the losses individually (e.g., based on respective gradient descents of the losses) through the network, or determine a combined loss (e.g., as an average of the losses) and backpropagate the combined loss through the network (e.g., based on a gradient descent of the combined loss). Then, ANN 300 may start another iteration of the training during which samplers 320a-320c may predict another set of sampling patterns 322a-322c and reconstructor 340 may predict another set of MRI images 304a-304c using the updated network parameters. In examples, based on the results accomplished by ANN 300 and the target/desired results, ANN 300 may adjust the sampling patterns predicted by samplers 320a-320c by manipulating the threshold value used to binarize the probability maps generated by samplers 320a-320c or by scaling the probability maps, for example, based on a ratio between a target acceleration rate and an actual acceleration rate presently accomplished by ANN 300.

It should be noted here that the connections shown in FIG. 3 between quality criteria 306 and sampler 320a-320c and between quality criteria 306 and reconstructor 340 are meant to illustrate that the operations of the samplers and/or reconstructor may be governed by quality criteria 306. The connections do not necessarily mean that quality criteria 306 are provided as an input to the samplers and/or reconstructor, even though that may be the case in some examples.

By fine-tuning its parameters based on the one or more losses described herein, ANN 300 may acquire the ability to jointly determine the sampling patterns and reconstruction algorithms (e.g., respective network parameters used to reconstruct MRI images 304a-304c) for the multiple contrasts that satisfy quality criteria 306. For example, through the end-to-end training process described above, ANN 300 may decide to adopt a first k-space sampling pattern and a first reconstruction algorithm (e.g., a first set of reconstruction parameters) for a first contrast image, and adopt a second k-space sampling pattern and a second reconstruction algorithm (e.g., a second set of reconstruction parameters) for a second contrast image. Since the training is guided (e.g., constrained) by quality criteria designed to optimize the overall performance of the multi-contrast MRI study (e.g., rather than each individual contrast), ANN 300 may learn to allocate resources for the multiple contrasts (e.g., by applying respective sampling patterns and reconstruction algorithms to the multiple contrasts) in a manner that improves the quality of the whole MRI study. Further, by exposing ANN 300 to different quality criteria during the training, ANN 300 may be able to apply suitable sampling patterns and/or reconstruction techniques to generating multi-contrast MRI images even if quality criteria imposed at a run-time (e.g., post-training) are different than those used during the training.

It should be noted that the network structure and/or operations shown in FIG. 3 are only examples, and those skilled in the art will appreciate that ANN 300 (e.g., reconstructor 340) may be implemented using various network structures. For example, those skilled in the art will appreciate that the sampling and/or reconstruction operations for the multiple contrasts may be performed sequentially, for example, using a recurrent neural network (RNN). Such an RNN may be trained, for example, to reconstruct an image with a second contrast based on an image constructed for a first contrast, e.g., as illustrated in FIG. 2.

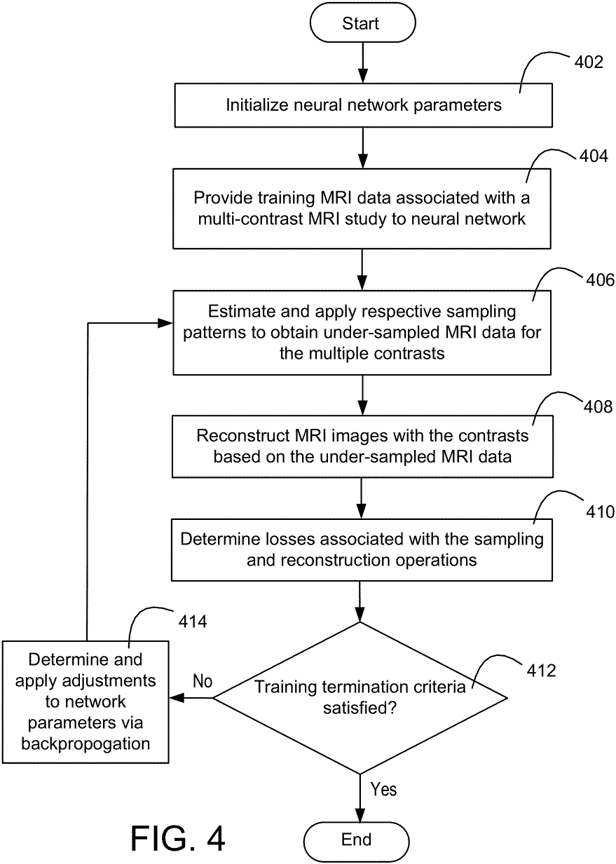

FIG. 4 illustrates example operations that may be performed while training a neural network (e.g., the neural network 100 of FIG. 1, 200 of FIG. 2, or 300 of FIG. 3) to perform the joint sampling and reconstruction tasks described herein. As shown, the training operations may include initializing parameters of the neural network (e.g., weights associated with the various filters or kernels of the neural network) at 402, for example, based on samples collected from one or more probability distributions or parameter values of another neural network having a similar architecture. The training operations may further include providing training data associated with a multi-contrast MRI study (e.g., fully sampled k-space data) to the neural network at 404, and causing the neural network to estimate and apply respective sampling patterns to the training data to obtain under-sampled k-space data for each contrast at 406. The training operations may also include reconstructing MRI images based on the under-sampled k-space data for the multiple contrasts at 408 and determining various losses based on the outcome of the sampling and reconstruction operations and a desired outcome at 410. The losses may be determined using a suitable loss function (e.g., L1, L2, SSIM, etc.) and may include, for example, respective losses between the images reconstructed by the neural network and corresponding ground truth images. The losses may also include a difference between a set of target quality criteria (e.g., an overall acceleration rate or scan time) and the quality actually achieved by the neural network. The losses may additionally include a loss determined based on a down-stream task such as a fitted T1 map that may be generated using one or more the reconstructed MRI images.

Once determined, the losses may be evaluated at 412, e.g., individually or as a combined loss (e.g., an average of the determined losses), to determine whether one or more training termination criteria have been satisfied. For example, a training termination criterion may be deemed satisfied if the loss(es) described above is below a predetermined thresholds, if a change in the loss(es) between two training iterations (e.g., between consecutive training iterations) falls below a predetermined threshold, etc. If the determination at 412 is that a training termination criterion has been satisfied, the training may end. Otherwise, the losses may be backpropagated (e.g., individually or as a combined loss) through the neural network (e.g., based on respective gradient descents associated with the losses or the gradient descent of the combined loss) at 414 before the training returns to 406.

For simplicity of explanation, the training steps are depicted and described herein with a specific order. It should be appreciated, however, that the training operations may occur in various orders, concurrently, and/or with other operations not presented or described herein. Furthermore, it should be noted that not all operations that may be included in the training process are depicted and described herein, and not all illustrated operations are required to be performed.

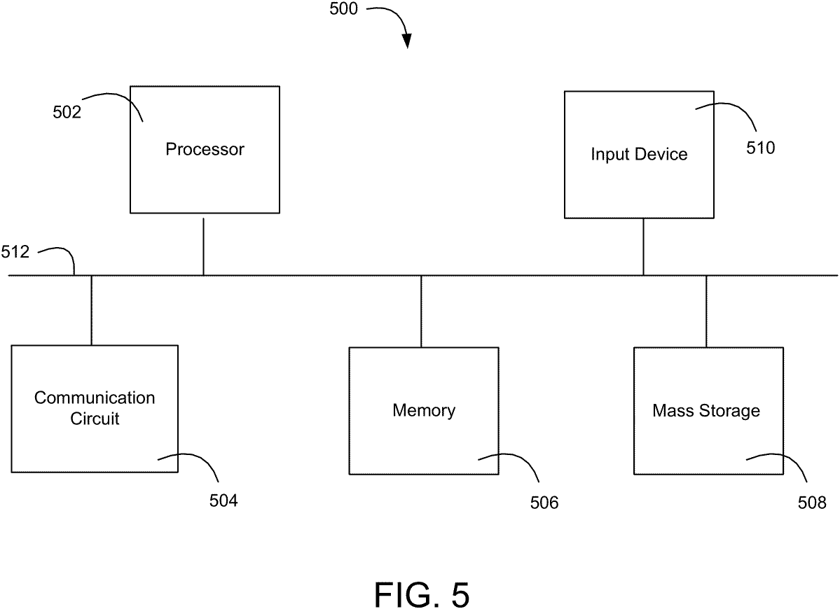

The systems, methods, and/or instrumentalities described herein may be implemented using one or more processors, one or more storage devices, and/or other suitable accessory devices such as display devices, communication devices, input/output devices, etc. FIG. 5 is a block diagram illustrating an example apparatus 500 that may be configured to perform the joint sampling and reconstruction tasks described herein. As shown, the apparatus 500 may include a processor (e.g., one or more processors) 502, which may be a central processing unit (CPU), a graphics processing unit (GPU), a microcontroller, a reduced instruction set computer (RISC) processor, application specific integrated circuits (ASICs), an application-specific instruction-set processor (ASIP), a physics processing unit (PPU), a digital signal processor (DSP), a field programmable gate array (FPGA), or any other circuit or processor capable of executing the functions described herein. The apparatus 500 may further include a communication circuit 504, a memory 506, a mass storage device 508, an input device 510, and/or a communication link 512 (e.g., a communication bus) over which the one or more components shown in the figure may exchange information.

The communication circuit 504 may be configured to transmit and receive information utilizing one or more communication protocols (e.g., TCP/IP) and one or more communication networks including a local area network (LAN), a wide area network (WAN), the Internet, a wireless data network (e.g., a Wi-Fi, 3G, 4G/LTE, or 5G network). The memory 506 may include a storage medium (e.g., a non-transitory storage medium) configured to store machine-readable instructions that, when executed, cause the processor 502 to perform one or more of the functions described herein. Examples of the machine-readable medium may include volatile or nonvolatile memory including but not limited to semiconductor memory (e.g., electrically programmable read-only memory (EPROM), electrically erasable programmable read-only memory (EEPROM)), flash memory, and/or the like. The mass storage device 508 may include one or more magnetic disks such as one or more internal hard disks, one or more removable disks, one or more magneto-optical disks, one or more CD-ROM or DVD-ROM disks, etc., on which instructions and/or data may be stored to facilitate the operation of the processor 502. The input device 510 may include a keyboard, a mouse, a voice-controlled input device, a touch sensitive input device (e.g., a touch screen), and/or the like for receiving user inputs to the apparatus 500.

It should be noted that the apparatus 500 may operate as a standalone device or may be connected (e.g., networked, or clustered) with other computation devices to perform the functions described herein. And even though only one instance of each component is shown in FIG. 5, a skilled person in the art will understand that the apparatus 500 may include multiple instances of one or more of the components shown in the figure.

While this disclosure has been described in terms of certain embodiments and generally associated methods, alterations and permutations of the embodiments and methods will be apparent to those skilled in the art. Accordingly, the above description of example embodiments does not constrain this disclosure. Other changes, substitutions, and alterations are also possible without departing from the spirit and scope of this disclosure. In addition, unless specifically stated otherwise, discussions utilizing terms such as “analyzing,” “determining,” “enabling,” “identifying,” “modifying” or the like, refer to the actions and processes of a computer system, or similar electronic computing device, that manipulates and transforms data represented as physical (e.g., electronic) quantities within the computer system’s registers and memories into other data represented as physical quantities within the computer system memories or other such information storage, transmission or display devices.

It is to be understood that the above description is intended to be illustrative, and not restrictive. Many other implementations will be apparent to those of skill in the art upon reading and understanding the above description. The scope of the disclosure should, therefore, be determined with reference to the appended claims, along with the full scope of equivalents to which such claims are entitled.

What is claimed is:

1. An apparatus, comprising:
one or more processors configured to:
determine, using an artificial neural network (ANN), a first magnetic resonance imaging (MRI) data sampling pattern for generating a first MRI image and a second MRI data sampling pattern for generating a second MRI image, wherein the first MRI image is characterized by a first contrast, the second MRI image is characterized by a second contrast, and the ANN is trained to determine the second MRI data sampling pattern in connection with the first MRI data sampling pattern so as to meet one or more quality criteria associated with the first MRI image and the second MRI image;
generate, using the ANN, the first MRI image based on a first set of under-sampled MRI data acquired using the first MRI data sampling pattern; and
generate, using the ANN, the second MRI image based on a second set of under-sampled MRI data acquired using the second MRI data sampling pattern.

2. The apparatus of claim 1, wherein the first MRI image is generated using a first set of parameters of the ANN, the second MRI image is generated using a second set of parameters of the ANN, and the ANN is trained to determine the second set of parameters in connection with the first set of parameters so as to meet the one or more quality criteria.

3. The apparatus of claim 1, wherein the ANN is trained to generate the first MRI image and the second MRI image in a sequential order, the second MRI image generated subsequent to and based on the first MRI image.

4. The apparatus of claim 1, wherein the ANN is trained to generate the first MRI image in parallel with the second MRI image.

5. The apparatus of claim 1, wherein the one or more quality criteria include an overall acceleration rate and the ANN is trained to determine the first MRI data sampling pattern and the second MRI data sampling pattern so as to generate the first MRI image and the second MRI image with respective acceleration rates to satisfy the overall acceleration rate.

6. The apparatus of claim 1, wherein the one or more quality criteria are further associated with a third MRI image and the one or more processors are further configured to:
determine, using the ANN, a third MRI data sampling pattern for generating the third MRI image, wherein the ANN is trained to determine the third MRI data sampling pattern in connection with at least one of the first MRI data sampling pattern or the second MRI data sampling pattern so as to satisfy the one or more quality criteria; and
generate, using the ANN, the third MRI image based on a third set of under-sampled MRI data acquired using the third MRI data sampling pattern.

7. The apparatus of claim 1, wherein the ANN is trained through a training process that comprises: receiving a training dataset that comprises MRI data;
determining a first estimated sampling pattern associated with generating a first MRI contrast image;
obtaining first under-sampled MRI data by applying the first estimated sampling pattern to the MRI data comprised in the training dataset;
generating the first MRI contrast image based on the first under-sampled MRI data;
determining a second estimated sampling pattern associated with generating a second MRI contrast image;
obtaining second under-sampled MRI data by applying the second estimated sampling pattern to the MRI data comprised in the training dataset;
generating the second MRI contrast image based on the second under-sampled MRI data; and
adjusting parameters of the ANN based on at least a first loss representing a difference between a target quality metric associated with generating the first MRI contrast image and the second MRI contrast image and an actual quality metric accomplished by the ANN.

8. The apparatus of claim 7, wherein the target quality metric includes a target overall acceleration rate or a target overall scan time, and the actual quality metric includes an actual overall acceleration rate or an actual overall scan time accomplished by the ANN.

9. The apparatus of claim 7, wherein the parameters of the ANN are further adjusted during the training process based on a second loss that represents respective differences between the first MRI contrast image and a first ground truth image and between the second MRI contrast image and a second ground truth image.

10. The apparatus of claim 1, wherein the first MRI image is a T1-weighted MRI image and the second MRI image is a T2-weighted MRI image.

11. A method for reconstructing magnetic resonance imaging (MRI) images, comprising:
determining, using an artificial neural network (ANN), a first magnetic resonance imaging (MRI) data sampling pattern for generating a first MRI image and a second MRI data sampling pattern for generating a second MRI image, wherein the first MRI image is characterized by a first contrast, the second MRI image is characterized by a second contrast, and the ANN is trained to determine the second MRI data sampling pattern in connection with the first MRI data sampling pattern so as to meet one or more quality criteria associated with the first MRI image and the second MRI image;
generating, using the ANN, the first MRI image based on a first set of under-sampled MRI data acquired using the first MRI data sampling pattern; and
generating, using the ANN, the second MRI image based on a second set of under-sampled MRI data acquired using the second MRI data sampling pattern.

12. The method of claim 11, wherein the first MRI image is generated using a first set of parameters of the ANN, the second MRI image is generated using a second set of parameters of the ANN, and the ANN is trained to determine the second set of parameters in connection with the first set of parameters so as to meet the one or more quality criteria.

13. The method of claim 11, wherein the ANN is trained to generate the first MRI image and the second MRI image in a sequential order, the second MRI image generated subsequent to and based on the first MRI image.

14. The method of claim 11, wherein the ANN is trained to generate the first MRI image in parallel with the second MRI image.

15. The method of claim 11, wherein the one or more quality criteria include an overall acceleration rate and the ANN is trained to determine the first MRI data sampling pattern and the second MRI data sampling pattern so as to generate the first MRI image and the second MRI image with respective acceleration rates to satisfy the overall acceleration rate.

16. The method of claim 11, wherein the one or more quality criteria are further associated with a third MRI image and the method further comprises:
determining, using the ANN, a third MRI data sampling pattern for generating the third MRI image, wherein the ANN is trained to determine the third MRI data sampling pattern in connection with at least one of the first MRI data sampling pattern or the second MRI data sampling pattern so as to satisfy the one or more quality criteria; and
generating, using the ANN, the third MRI image based on a third set of under-sampled MRI data acquired using the third MRI data sampling pattern.

17. The method of claim 11, wherein the ANN is trained through a training process that comprises: receiving a training dataset that comprises MRI data;
determining a first estimated sampling pattern associated with generating a first MRI contrast image;
obtaining first under-sampled MRI data by applying the first estimated sampling pattern to the MRI data comprised in the training dataset;
generating the first MRI contrast image based on the first under-sampled MRI data;
determining a second estimated sampling pattern associated with generating a second MRI contrast image;
obtaining second under-sampled MRI data by applying the second estimated sampling pattern to the MRI data comprised in the training dataset;
generating the second MRI contrast image based on the second under-sampled MRI data; and
adjusting parameters of the ANN based on at least a first loss representing a difference between a target quality metric associated with generating the first MRI contrast image and the second MRI contrast image and an actual quality metric accomplished by the ANN.

18. The method of claim 17, wherein the target quality metric includes a target overall acceleration rate or a target overall scan time, and the actual quality metric includes an actual overall acceleration rate or an actual overall scan time accomplished by the ANN.

19. The method of claim 17, wherein the parameters of the ANN are further adjusted during the training process based on a second loss that represents respective differences between the first MRI contrast image and a first ground truth image and between the second MRI contrast image and a second ground truth image.

20. The method of claim 11, wherein the first MRI image is a T1-weighted MRI image and the second MRI image is a T2-weighted MRI image.
